(19) United States
(12) Patent Application Publication
(10) Pub. No.: US 2025/0169160 A1
(43) Pub. Date: May 22, 2025

(54) DUAL LINERS FOR AGGRESSIVE NANOSHEET SPACING WITH BACKSIDE CONTACTS

(71) Applicant: International Business Machines Corporation, Armonk, NY (US)

(72) Inventors: Liqiao Qin, Albany, NY (US); Tao Li, Slingerlands, NY (US); Ruilong Xie, Niskayuna, NY (US); John Christopher Arnold, North Chatham, NY (US)

(21) Appl. No.: 18/510,760

(22) Filed: Nov. 16, 2023

(51) Int. Cl. H01L 21/8238; H01L 27/092; H01L 29/06; H01L 29/423; H01L 29/66; H01L 29/775; H01L 29/786

(52) U.S. Cl. CPC H10D 84/038; H10D 30/014; H10D 30/43; H10D 30/6735; H10D 30/6757; H10D 62/121; H10D 64/017; H10D 84/0167; H10D 84/0186; H10D 84/0188; H10D 84/85

(57) ABSTRACT

Embodiments of the present disclosure include a semiconductor structure having a transistor adjacent to a shallow trench isolation (STI) region. The STI region includes a first liner, a second liner, and fill material. The second liner is pinched off in a portion of the STI region. A backside contact is coupled to the transistor, the first liner, and the second liner.

### BACKGROUND

The present invention generally relates to fabrication methods and resulting structures for integrated circuits (ICs), and more specifically, to fabrication methods and resulting structures for nanosheet field-effect transistors having dual shallow trench isolation liners for aggressive nanosheet spacing with backside contacts and backside power delivery network.

ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer. on the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a FinFET device, which is a three-dimensional structure. One type of device that shows promise for advanced integrated circuit products of the future is generally known as a nanosheet transistor. In general, a nanosheet transistor has a fin-type channel structure that includes a plurality of vertically spaced-apart sheets of semiconductor material. A gate structure for the device is positioned around each of these spaced-apart layers of channel semiconductor material.

### SUMMARY

Embodiments of the present invention are directed to nanosheet field-effect transistors having dual shallow trench isolation liners for aggressive nanosheet spacing with backside contacts and a backside power delivery network. A non-limiting method of forming a semiconductor structure includes providing a transistor adjacent to a shallow trench isolation (STI) region, the STI region including a first liner, a second liner, and fill material, the second liner being pinched off in a portion of the STI region. The method includes coupling a backside contact to the transistor, the first liner, and the second liner.

According to one or more embodiments, a non-limiting method of forming a semiconductor structure includes providing a first transistor and second transistor separated by a STI region, the STI region including a first liner, a second liner, and fill material, the second liner being pinched off in a portion of the STI region. The method includes coupling backside contacts to the first and second transistors, the first liner, and the second liner.

Other embodiments of the present invention implement features of the above-described devices/structures in methods and/or implement features of the methods in devices/structures.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIGS. 1A and 1B respectively depict a top view and cross-sectional view of a portion of an integrated circuit (IC) under-fabrication after fabrication operations according to one or more embodiments of the invention;

FIGS. 2A, 2B, 2C, and 2D respectively depict a top view and cross-sectional views of a portion of an IC under-fabrication after fabrication operations according to one or more embodiments of the invention;

FIGS. 3A, 3B, 3C, and 3D respectively depict a top view and cross-sectional views of a portion of an IC under-fabrication after fabrication operations according to one or more embodiments of the invention;

FIGS. 4A, 4B, 4C, and 4D respectively depict a top view and cross-sectional views of a portion of an IC under-fabrication after fabrication operations according to one or more embodiments of the invention;

FIGS. 5A, 5B, 5C, and 5D respectively depict a top view and cross-sectional views of a portion of an IC under-fabrication after fabrication operations according to one or more embodiments of the invention;

FIGS. 6A, 6B, 6C, and 6D respectively depict a top view and cross-sectional views of a portion of an IC under-fabrication after fabrication operations according to one or more embodiments of the invention;

FIGS. 7A, 7B, 7C, and 7D respectively depict a top view and cross-sectional views of a portion of an IC under-fabrication after fabrication operations according to one or more embodiments of the invention;

FIGS. 8A, 8B, 8C, and 8D respectively depict a top view and cross-sectional views of a portion of an IC under-fabrication after fabrication operations according to one or more embodiments of the invention;

FIGS. 9A, 9B, 9C, and 9D respectively depict a top view and cross-sectional views of a portion of an IC under-fabrication after fabrication operations according to one or more embodiments of the invention;

FIGS. 10A, 10B, 10C, and 10D respectively depict a top view and cross-sectional views of a portion of an IC under-fabrication after fabrication operations according to one or more embodiments of the invention;

FIGS. 11A, 11B, 11C, and 11D respectively depict a top view and cross-sectional views of a portion of an IC under-fabrication after fabrication operations according to one or more embodiments of the invention;

FIGS. 12A, 12B, 12C, and 12D respectively depict a top view and cross-sectional views of a portion of an IC under-fabrication after fabrication operations according to one or more embodiments of the invention;

FIGS. 13A, 13B, 13C, and 13D respectively depict a top view and cross-sectional views of a portion of an IC under-fabrication after fabrication operations according to one or more embodiments of the invention;

FIG. 14 depicts a flowchart of a method of forming a semiconductor structure according to one or more embodiments of the invention; and

FIG. 15 depicts a flowchart of a method of forming a semiconductor structure according to one or more embodiments of the invention.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

The MOSFET is a transistor used for amplifying or switching electronic signals. The MOSFET has a source, a drain, and a metal gate electrode. The metal gate is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (NFET) and p-type field effect transistors (PFET) are two types of complementary MOSFETs. The NFET includes n-doped source and drain junctions and uses electrons as the current carriers. The PFET includes p-doped source and drain junctions and uses holes as the current carriers.

The nanowire or nanosheet MOSFET is a type of MOSFET that uses multiple stacked nanowires/nanosheets to form multiple channel regions. The gate regions of a nanosheet MOSFET are formed by wrapping gate stack materials around the multiple nanowire/nanosheet channels. This configuration is known as a gate-all-around (GAA) FET structure. The nanowire/nanosheet MOSFET device mitigates the effects of short channels and reduces drain-induced barrier lowering.

The GAA nanosheet FET structures can provide superior electrostatics. In contrast to known Fin-type FET (FinFET) structures in which the fin element of the transistor extends “up” out of the transistor, nanosheet FET designs implement the fin as a silicon nanosheet/nanowire. In a known configuration of a GAA nanosheet FET, a relatively small FET footprint is provided by forming the channel region as a series of nanosheets (i.e., silicon nanowires). A known GAA configuration includes a source region, a drain region, and stacked nanosheet channels between the source and drain regions. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized.

IC structures often incorporate multiple FETs such as NFETs and PFETs. The spacing between nanosheets stacked to form stacked nanosheet channels of nanosheet FETs is becoming smaller. This results in very narrow shallow trench isolation regions that become difficult to fill, which can result in gaps or holes in the fill material. One or more embodiments provide fabrication methods and resulting nanosheet field-effect transistors and their corresponding backside contacts using a dual shallow trench isolation (STI) liner approach. Using the dual STI liner approach, an upper STI liner is formed on a lower STI liner in the trench and the upper STI liner is utilized to pinch off the small isolation space between transistors, particularly the small space between an n-type transistor and p-type transistor, in order to avoid a fill gap in the narrowest portion of the trench. The lower STI line can also serve as a etch stop layer during backside contact patterning process.

Technical benefits and effects enable the formation of tightly spaced n-type and p-type transistors, where the small space of the STI trench in the active region is formed with the lower and upper liners in which the upper liner pinches off the narrowest portion of the STI trench. The larger portion of the STI trench at the top can be filled with interlayer dielectric fill material.

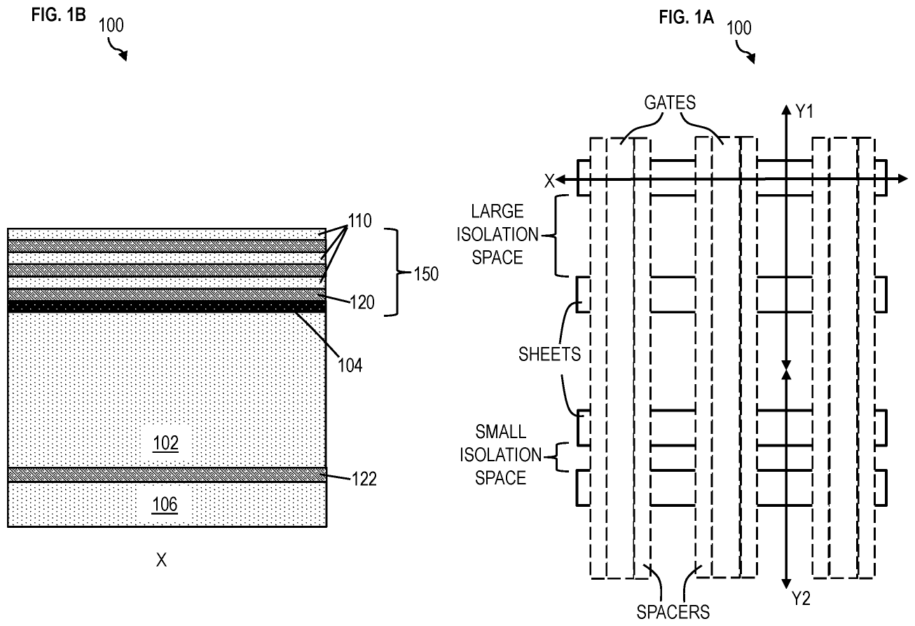

Turning now to a more detailed description of aspects of the present invention, FIG. 1A depicts a top view of a simplified illustration of a portion of an integrated circuit (IC) 100 and FIG. 1B depicts a cross-sectional view taken along X of the IC 100. Additional cross-sectional views along Y1 and Y2 are illustrated in subsequent figures. For ease of understanding, some layers may be omitted from the various top views so as not to obscure the figure and to view layers underneath. As such, the top view is intended to provide a simplified illustration and a general orientation. Some future locations of features may be illustrated in the top view. Standard semiconductor fabrication techniques can be utilized to fabricate IC 100 as understood by one of ordinary skill in the art. Any suitable lithography processes including deposition techniques and etching techniques can be utilized herein.

FIGS. 1A and 1B depict the IC 100 having a wafer where several fabrication processes have been performed. A nanosheet stack is formed on a substrate 102. The wafer or substrate 102 may be formed of (pure) silicon. Other suitable materials can be utilized for the substrate 102.

A nanosheet stack 150 of semiconductor layers 110 is formed with sacrificial layers 120 formed in between, and a sacrificial layer 122 is formed underneath the substrate 102. The sacrificial layer 122 is between the substrate 102 and a lower substrate 106. The lower substrate 106 may be formed of silicon. A sacrificial layer 104 is formed on top of the substrate 102. It is noted the sacrificial layer 122 is optional. In one or more embodiments, the sacrificial layer 122 is not present.

The semiconductor layers 110 may include substantially pure silicon. The semiconductor layers 110 will become the channel regions for the nanosheet FET device. The semiconductor layers 110 are nanosheets. Nanosheets can have a thickness of, for example, about 5 nanometers. The thickness of a nanosheet can range from about 5-10 nm, and other ranges are possible. The sacrificial layers 120 and 122 are formed of silicon germanium (SiGe), where germanium has an atomic percent (%) of about 25% and silicon is the remainder. In one or more embodiments, the atomic percent of germanium can range from about 15-30% while silicon is the remainder in the sacrificial layers 120 and 122. The sacrificial layer 104 is formed of silicon germanium (SiGe), where germanium has an atomic percent (%) of about 55% and silicon is the remainder. In one or more embodiments, the atomic percent of germanium can range from about 50-60% while silicon is the remainder in the sacrificial layer 104.

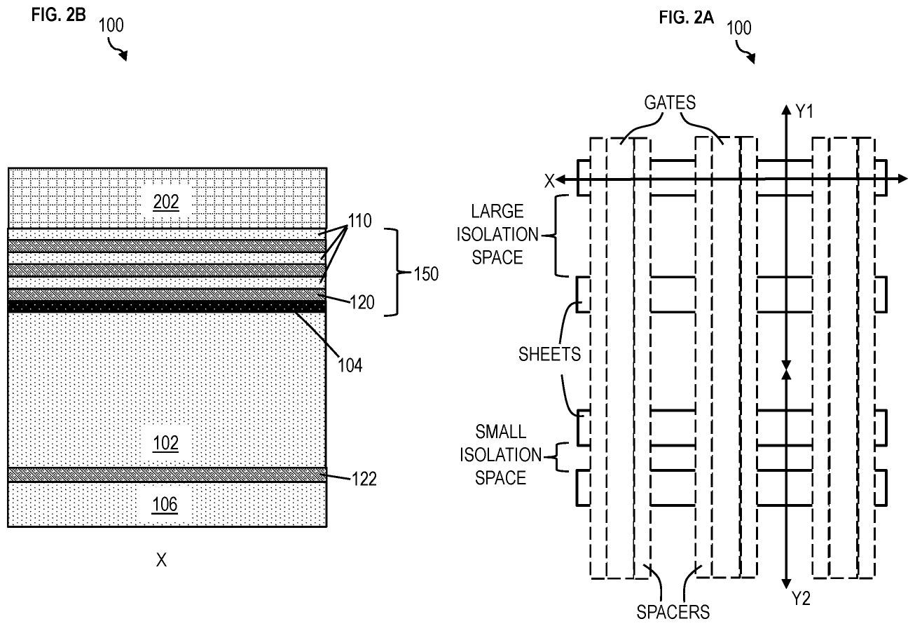

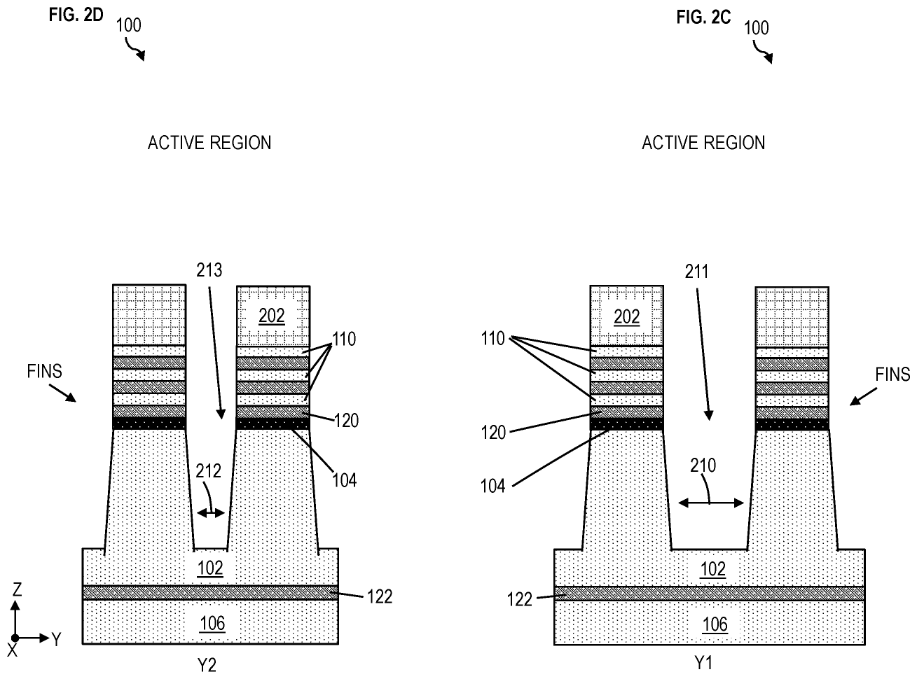

FIGS. 2A, 2B, 2C, and 2D depict the IC 100 after fin patterning. FIG. 2C depicts a cross-sectional view taken along Y1 of the IC 100, while FIG. 2D depicts a cross-sectional view taken along Y2 of the IC 100.

A hard mask layer 202 is formed and patterned. The patterned hard mask layer 202 is utilized to transfer the pattern into the nanosheet stack 150 and partially into the substrate 102, resulting in fins and STI trenches. FIG. 2C depicts a wide spacing 210 between fins that will result into transistors. In FIG. 2C, an STI trench 211 is formed with the wide spacing 210 in the y-axis, which tapers as the STI trench 211 proceeds downward in the z-axis. FIG. 2D depicts a narrow spacing 212 between fins that will result into transistors. In FIG. 2D, an STI trench 213 is formed with the narrow spacing 212 in the y-axis, which tapers as the STI trench 213 proceeds downward in the z-axis. The width of the STI trench 213 is smaller than the width of the STI trench 211, and the narrow STI trench 213 could result in fill gaps attempting to fill the narrowest portion at the bottom of the STI trench 213. Because of the narrow spacing 212 of the STI trench 213, a dual liner approach is utilized in the STI trenches as discussed further herein, thereby preventing fill gaps in the narrowest portion of the STI trench 213 according to one or more embodiments. Further, the fins and resulting transistors are closer in FIG. 2D than in FIG. 2C, for example, having a tighter fin/transistor pitch.

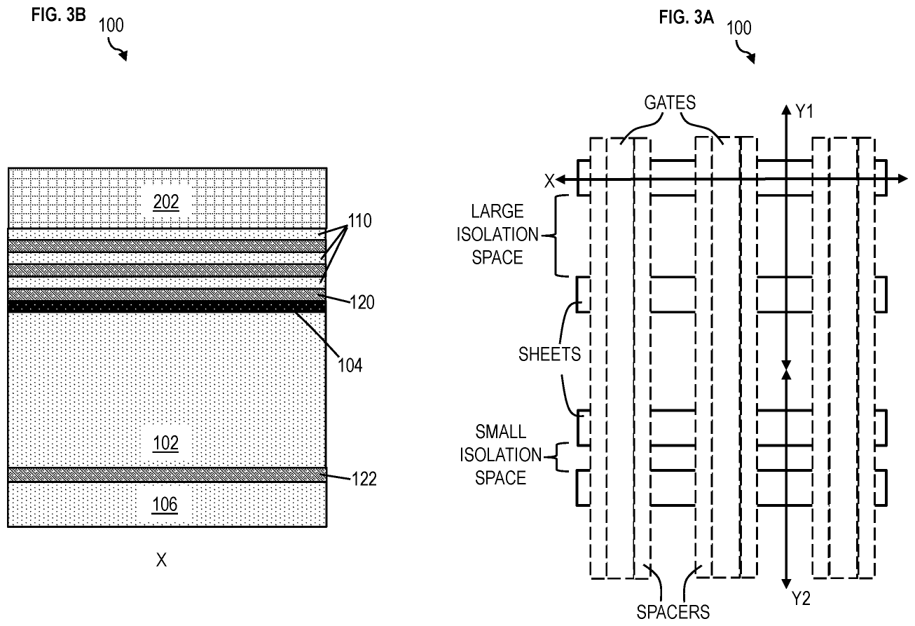

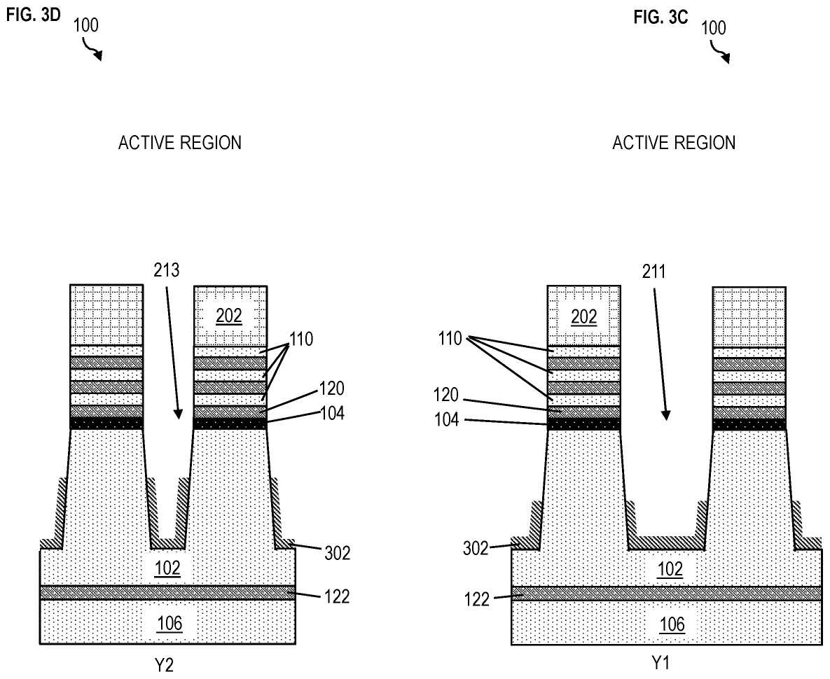

FIGS. 3A, 3B, 3C, and 3D depict the IC 100 after deposition of the first STI liner. The first STI liner 302 is deposited and followed by chamfering the first STI liner 302. The first STI liner 302 can be deposited using conformal deposition such as atomic layer deposition (ALD) and then etched back. Example materials of the first STI liner 302 may include hafnium oxide (HfO₂), aluminum nitride (AlN), etc. The first STI liner 302 can serve as an etch stop in backside processing as discussed herein.

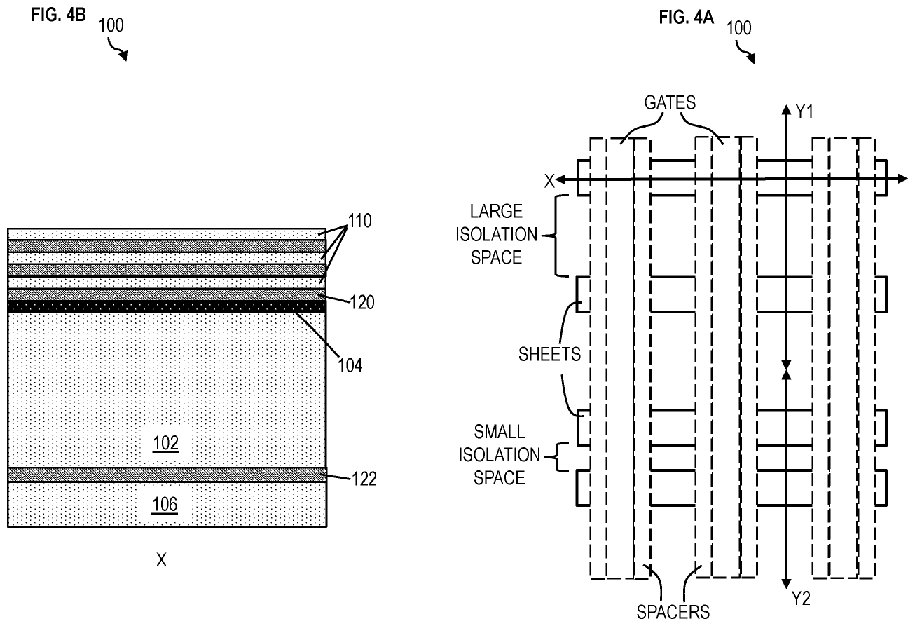

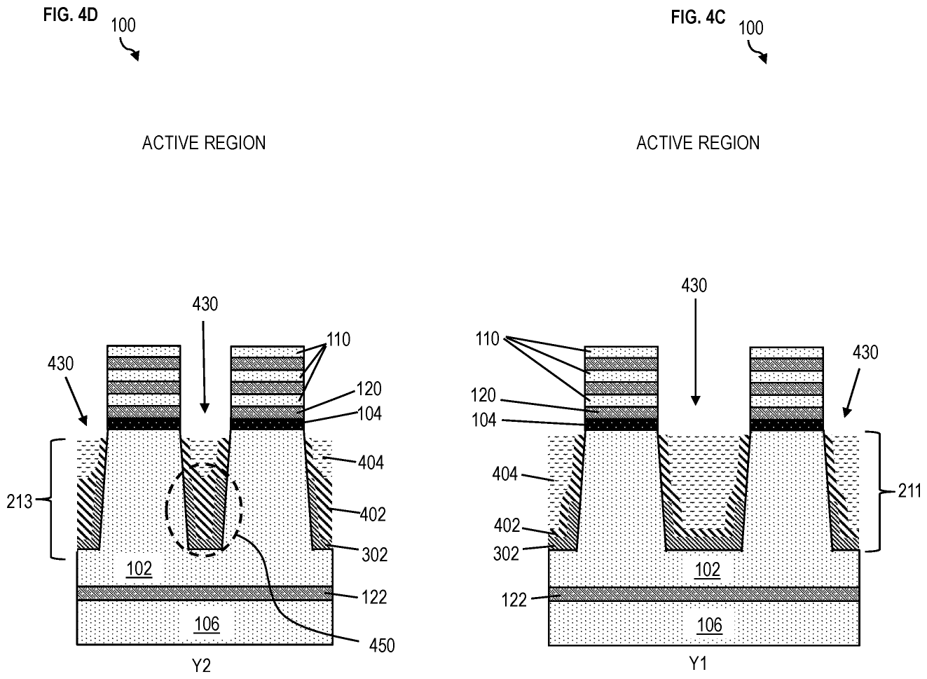

FIGS. 4A, 4B, 4C, and 4D depict the IC 100 after deposition of the second STI liner and STI fill material. The second STI liner 402 is deposited in the STI trenches 211 and 213. Pinch off of the second STI liner 402 occurs at the narrowest portions of the STI trench 213 as depicted by the dashed circle 450 in FIG. 4D, which means there will not be an air gap or hole in the narrowest portions of the STI trench 213, such as the middle or below. Pinch off may not occur in the wide spacing of the STI trench 211 in FIG. 4C, as the wide spacing can be filled by the STI fill material. The second STI liner 402 can deposited using conformal deposition such as ALD. Example materials of the second STI liner 402 may include silicon nitride (SiN). STI fill material 404 is deposited to fill the STI trenches 211 and 213, thereby forming STI regions 430. The STI fill material 404 may be an oxide material such as silicon dioxide (SiO₂). In one or more embodiments, the first STI liner 302, the second STI liner 402, and the STI fill material 404 are each different materials in the STI regions 430. Etching can be performed and the hard mask layer 202 is removed.

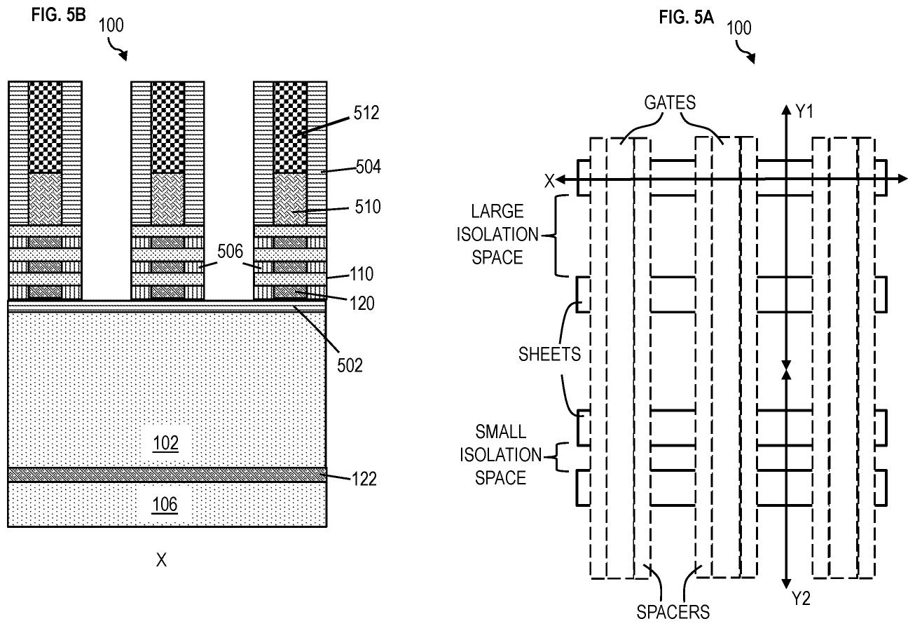

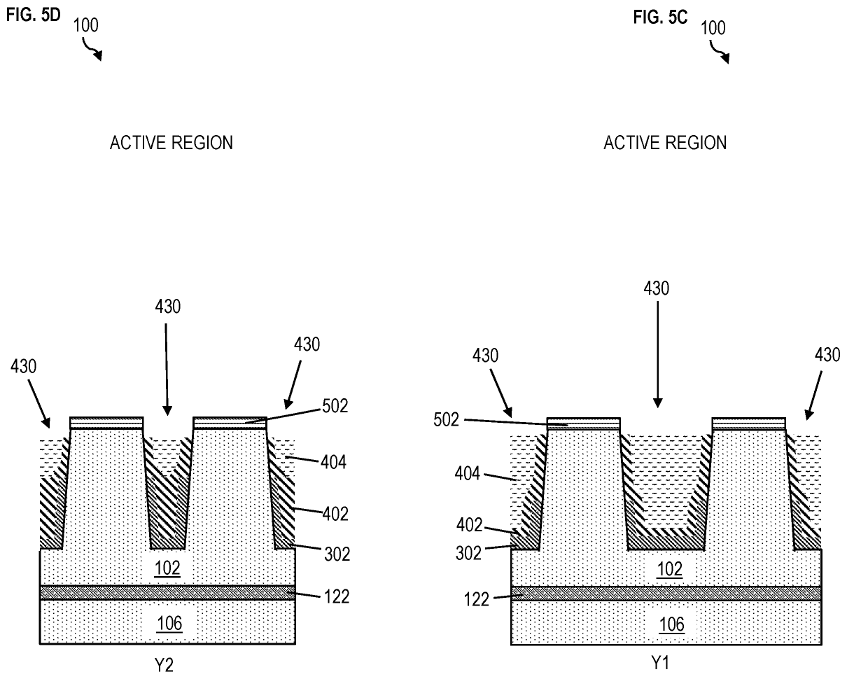

FIGS. 5A, 5B, 5C, and 5D depict the IC 100 after several typical fabrication processes including dummy gate formation, dummy gate patterning, bottom SiGe selective removal, gate spacer and bottom dielectric isolation bottom dielectric isolation layer formation, nanosheet recess, SiGe indentation, and inner spacer formation.

Sacrificial gate material is formed on the IC 100 to be a dummy gate 510, and a hard mask layer 512 is formed on top of the sacrificial gate material. The hard mask layer 512 is patterned, and the patterned hard mask layer is utilized to etch the sacrificial gate material into the dummy gate 510. Example materials of the dummy gate 510 can include amorphous silicon, polycrystalline silicon, etc. Example materials of the hard mask layer 512 can include nitride materials such as silicon nitride.

Gate spacer deposition and etching is performed resulting in gate spacer 504. The sacrificial layer 104 is selectively removed, leaving an empty cavity (not shown). It is noted that the sacrificial layer 104 has the highest atomic percent of germanium in the silicon germanium material, and the sacrificial layer 104 can be selectively etched versus the sacrificial layers 120 and the semiconductor layers 110. After that, gate spacer material is deposited at the sides of the dummy gate 510 as well as into the empty cavity left after removal of the sacrificial layer 104, resulting in bottom dielectric isolation layer 502. Etching is performed to form gate spacers 504 and bottom dielectric isolation layer 502. Example materials of the gate spacer 504 and the bottom dielectric isolation layer 502 can include nitride materials, such as SiN, SiBCN, SiOCN, SiOC, etc.

Nanosheet pulldown and inner space formation are performed. Directional etching is performed while using the hard mask layer 512 and the gate spacers 504 as a protective mask, in order to trim the nanosheet stack. As a result of the etching, the unprotected portions of the semiconductor layers 110 and the sacrificial layers 120 are removed. To form inner spacers 506, isotropic etching is performed to selectively remove end portions of the scarification layers 120 resulting in cavities at the ends. Inner spacer material is deposited to fill the cavities, and etching is performed to remove the excess spacer material, resulting in the inner spacers 506 on the ends of the sacrificial layers 120. Example materials of the inner spacers 506 can include nitrides, low-k dielectric materials, etc. Example materials of the inner spacers 506 may include SiBCN, SiOCN, SiN, SiOC, SiC, etc.

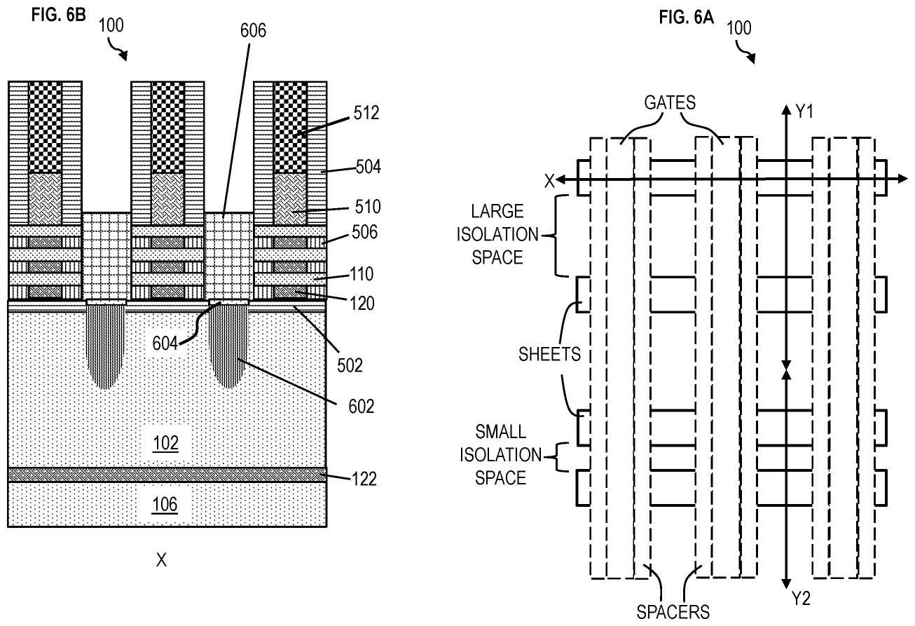

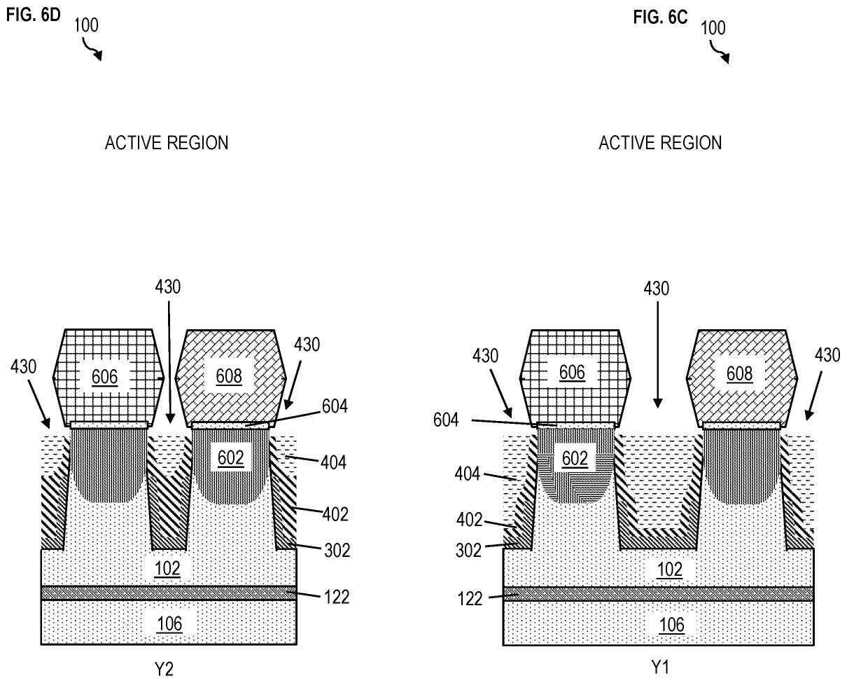

FIGS. 6A, 6B, 6C, and 6D depict the IC 100 after placeholder formation and source and drain epitaxial deposition. Placeholder etching is performed in the regions for the source and drains resulting in placeholder cavities. First placeholder material 602 is formed to fill the placeholder cavities, and a second placeholder material 604 is formed on top. The first and second placeholder materials 602 and 604 are different dielectric materials. Example materials of the first placeholder material 602 may include, for example, SiGe. Example materials of the second placeholder material 604 may include, for example, Si. Other example materials of the first and second placeholder materials 602 and 604 may include titanium oxides (TiOx) and aluminum oxides (AlOx).

To form epitaxial source/drain regions 606 and 608, semiconductor material is deposited and epitaxially grown from the nanosheet semiconductor layers 110. The semiconductor material can be doped with n-type or p-type dopants according to whether an n-type or p-type transistor (NFET or PFET) is being formed. For instance, the epitaxial material of the source/drain regions 606 can be doped with p-type dopants, for example, such as silicon germanium doped with boron (SiGe:B) when forming a PFET. For instance, the epitaxial material of the source/drain regions 608 can be doped with n-type dopants, for example, such as silicon doped with phosphorus (Si:P) when forming an NFET.

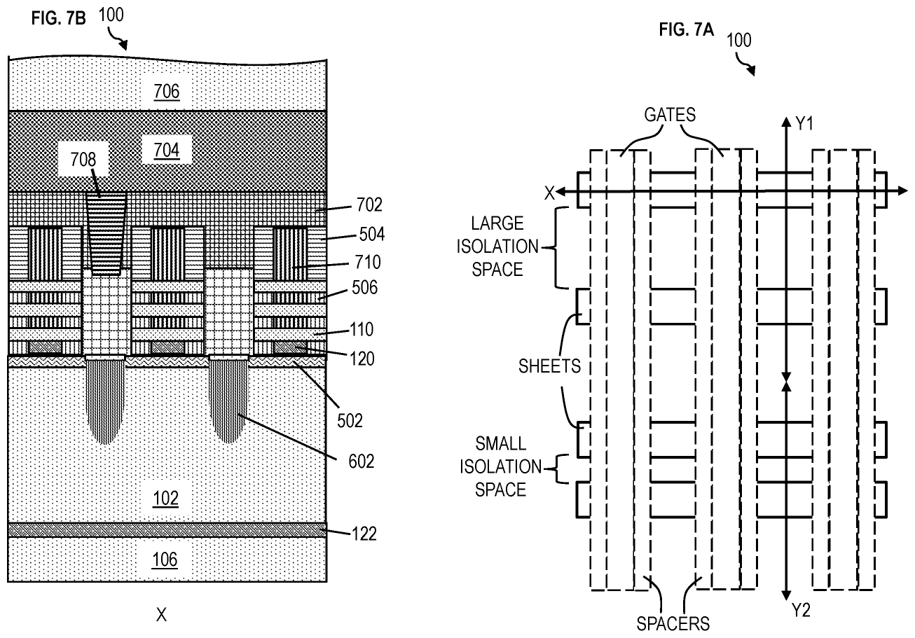

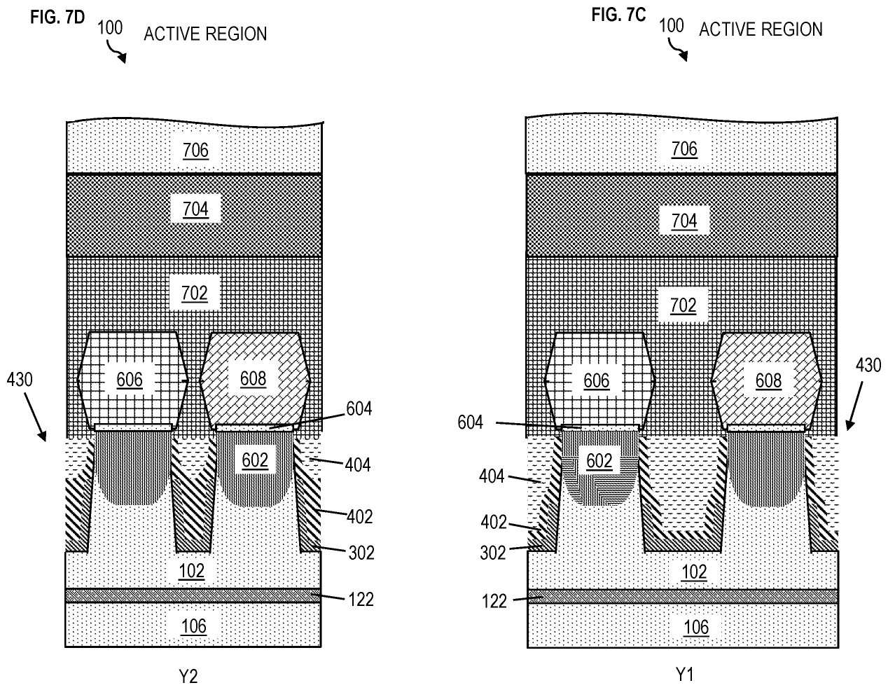

FIGS. 7A, 7B, 7C, and 7D depict the IC 100 after several fabrication processes including replacement metal gate (RMG) formation, interlayer/intralayer dielectric formation, middle-of-line (MOL) processing, back-end-of-line (BEOL) processing, and carrier wafer bonding.

Chemical mechanical planarization/polishing and etching can be performed, which can be a wet etch or dry etch, to remove the hard mask layer 512, dummy gates 510, a portion of the gate spacers 504, and sacrificial layers 120. The S/D regions 606 and 608 can be protected with a block mask (not shown). The RMG process is performed to deposit a high-k dielectric material followed by one or more work function material layers, thereby forming gate material 710. A cap layer (not shown) may be formed on top of the gate material 710.

Gate material 710 is formed around the semiconductor layers 110. The gate material 710 includes high-k material and work function material generally referred to as a high-k metal gate (HKMG). Techniques for forming HKMG in gate openings are well-known in the art and, thus, the details have been omitted in order to allow the reader to focus on the salient aspects of the disclosed methods. However, it should be understood that such HKMG will generally include formation of one or more gate dielectric layers (e.g., an inter-layer (IL) oxide and a high-k gate dielectric layer), which are deposited so as to line the gate openings, and formation of one or more metal layers, which are deposited onto the gate dielectric layer(s) so as to fill the gate openings. The materials and thicknesses of the dielectric and metal layers used for the HKMG can be preselected to achieve desired work functions given the conductivity type of the FET. To avoid clutter in the drawings and to allow the reader to focus on the salient aspects of the disclosed methods, the different layers within the HKMG stack are not illustrated. For explanation purposes, a high-k gate dielectric layer can be, for example, a dielectric material with a dielectric constant that is greater than the dielectric constant of silicon dioxide (i.e., greater than 3.9). Exemplary high-k dielectric materials include, but are not limited to, hafnium (Hf)-based dielectrics (e.g., hafnium oxide, hafnium silicon oxide, hafnium silicon oxynitride, hafnium aluminum oxide, etc.) or other suitable high-k dielectrics (e.g., aluminum oxide, tantalum oxide, zirconium oxide, etc.). Optionally, the metal layer(s) can include a work function metal that is immediately adjacent to the gate dielectric layer and that is preselected in order to achieve an optimal gate conductor work function given the conductivity type of the nanosheet-FET. For example, the optimal gate conductor work function for the PFETs can be, for example, between about 4.9 eV and about 5.2 eV. Exemplary metals (and metal alloys) having a work function within or close to this range include, but are not limited to, ruthenium, palladium, platinum, cobalt, and nickel, as well as metal oxides (aluminum carbon oxide, aluminum titanium carbon oxide, etc.) and metal nitrides (e.g., titanium nitride, titanium silicon nitride, tantalum silicon nitride, titanium aluminum nitride, tantalum aluminum nitride, etc.). The optimal gate conductor work function for NFETs can be, for example, between 3.9 eV and about 4.2 eV. Exemplary metals (and metal alloys) having a work function within or close to this range include, but are not limited to, hafnium, zirconium, titanium, tantalum, aluminum, and alloys thereof, such as, hafnium carbide, zirconium carbide, titanium carbide, tantalum carbide, and aluminum carbide. The metal layer(s) can further include a fill metal or fill metal alloy, such as tungsten, a tungsten alloy (e.g., tungsten silicide or titanium tungsten), cobalt, aluminum, or any other suitable fill metal or fill metal.

Interlayer dielectric (ILD) material 702 is deposited. The ILD material 702 can be a low-k dielectric material, an ultra-low-k dielectric material, etc. The ILD material 702 can include SiO₂, or low-k and ultra-low-k dielectric materials with a k-value <4. The ILD material 702 is patterned to open source/drain contact cavities (not shown) by conventional lithography. As part of the MOL processing, the cavities are filled with conductive material to form metal contacts, such as front side S/D contacts 708. A portion of the metal contacts may include silicide, resulting from the interface of the metal material and semiconductor material. BEOL processing is performed to form a BEOL layer 704. A carrier wafer 706 is bonded to the BEOL layer 704.

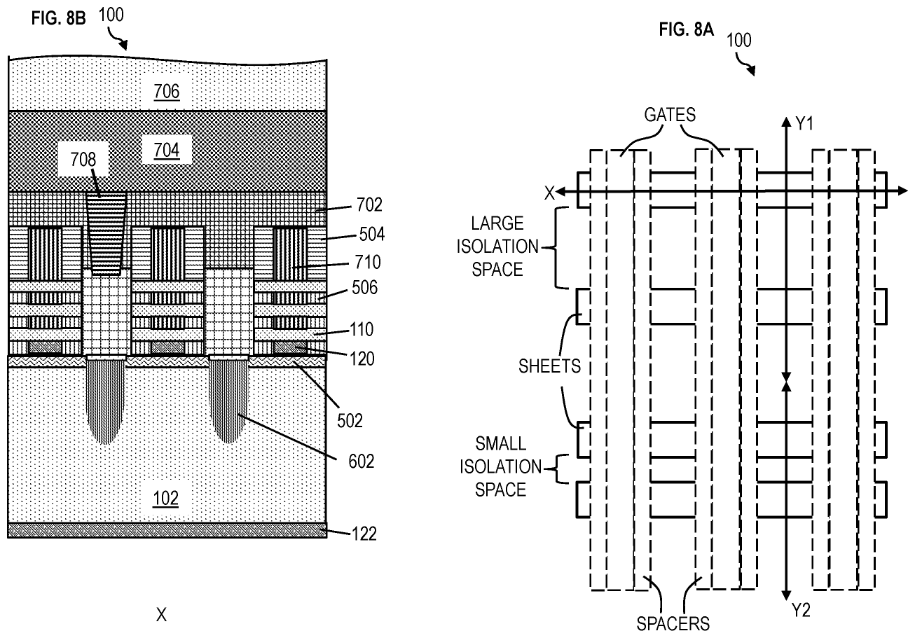

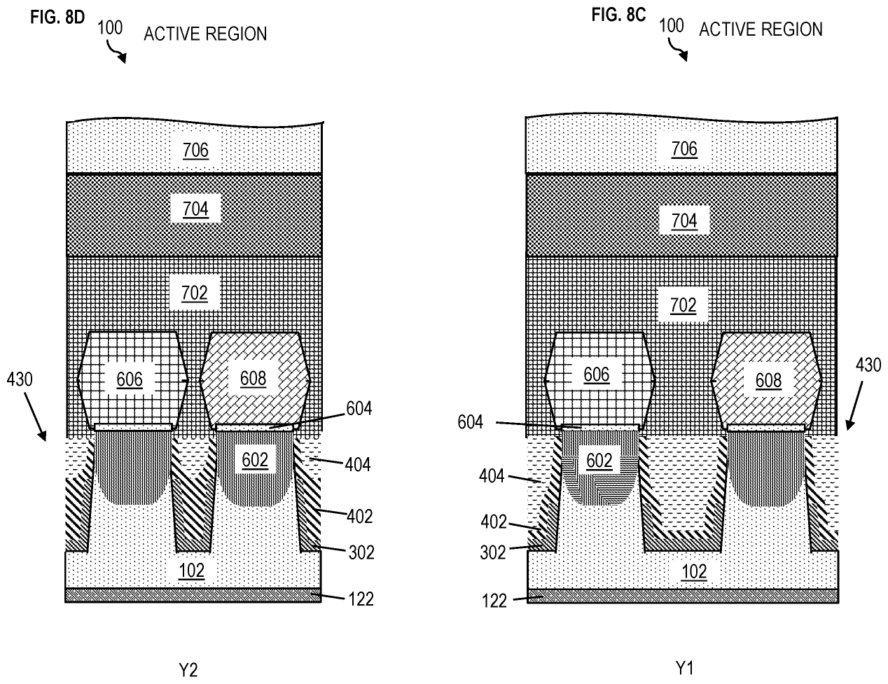

FIGS. 8A, 8B, 8C, and 8D depict the IC 100 after a wafer flip and removal of the lower substrate. For ease of understanding and to maintain a consistent orientation for the reader, the wafer is not flipped in the figures although the wafer is flipped during the fabrication process. Etching is performed to remove the lower substrate 106, which may include a CMP process while the sacrificial layer 122 serves as an etch stop.

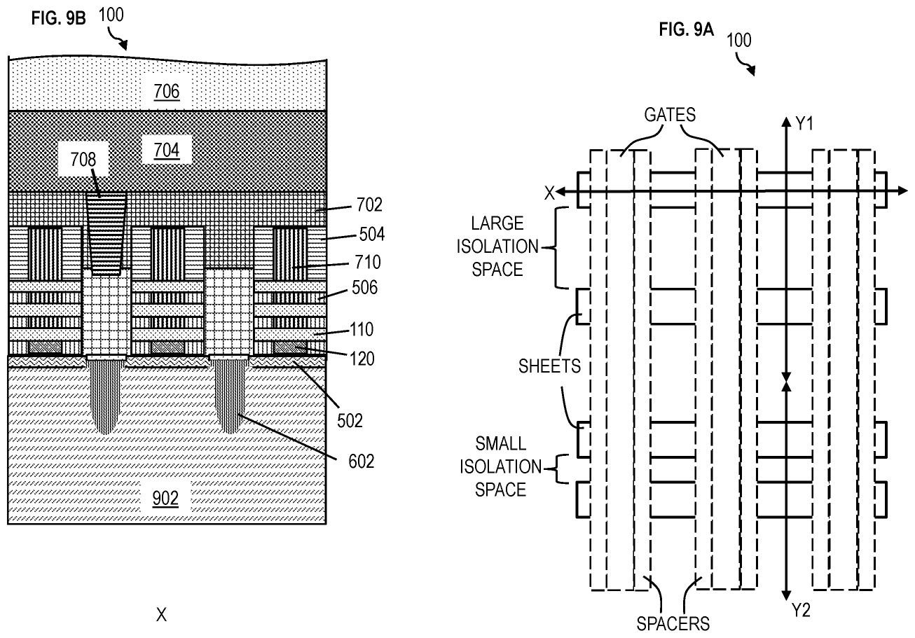

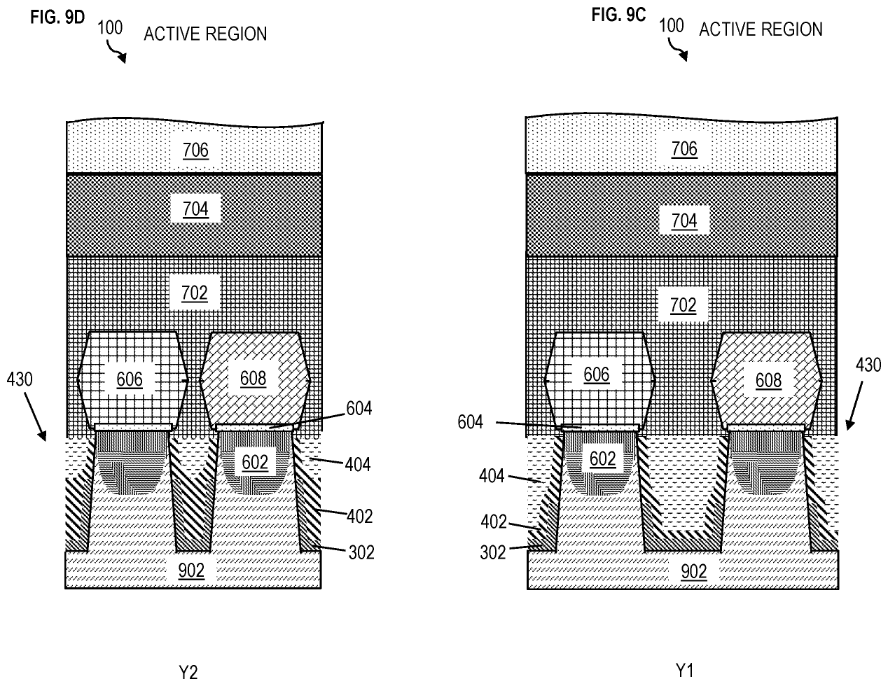

FIGS. 9A, 9B, 9C, and 9D depict the IC 100 after etch stop removal, upper substrate removal, and backside ILD fill. Selective etching can be performed to remove the sacrificial layer 122 and substrate 102. An example etchant to selectively remove the sacrificial layer 122 and the substrate 102 without removing the bottom dielectric isolation layer 502, the first placeholder material 602, the first STI liner 302, and the second STI liner 402 may include, for example, hot ammonia (NH₃). It is noted that the etching may etch some of the first placeholder material 602, thereby reducing its size. ILD fill material is deposited to form backside ILD material 902, and planarization is performed.

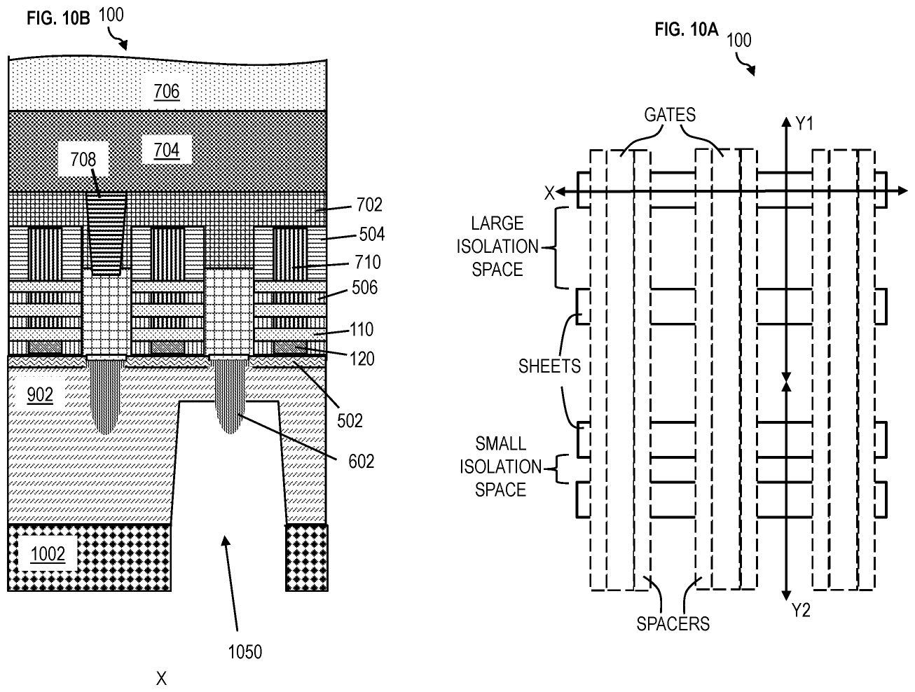

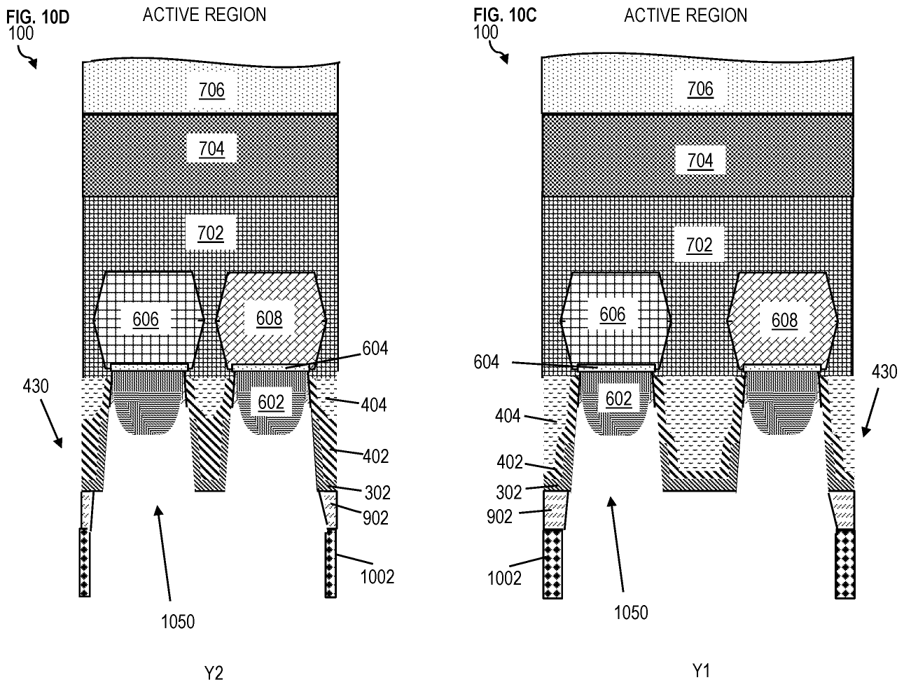

FIGS. 10A, 10B, 10C, and 10D depict the IC 100 after backside patterning. Lithography is performed to form trenches 1050 on the backside. For example, a block mask layer 1002 is deposited and patterned. The block mask layer 1002 may be an organic patterning layer (OPL) and/or any suitable material or combination of materials. Lithography is performed to open up the block mask layer 1002 at some locations to expose the first placeholder material 602. The block mask layer 1002 is to be utilized for protection while etching is performed to open the trenches 1050. The first STI liner 302 can serve as an etch stop. Further, the dual STI liners including both the first and second STI liners 302 and 402 serve to protect STI fill material 404 that could become damaged during the etching process.

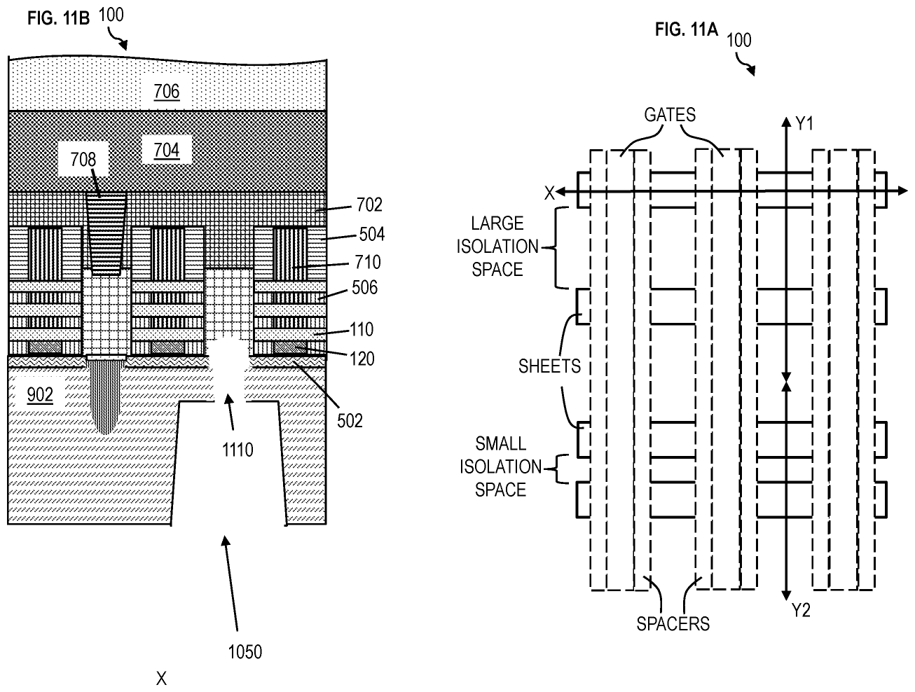

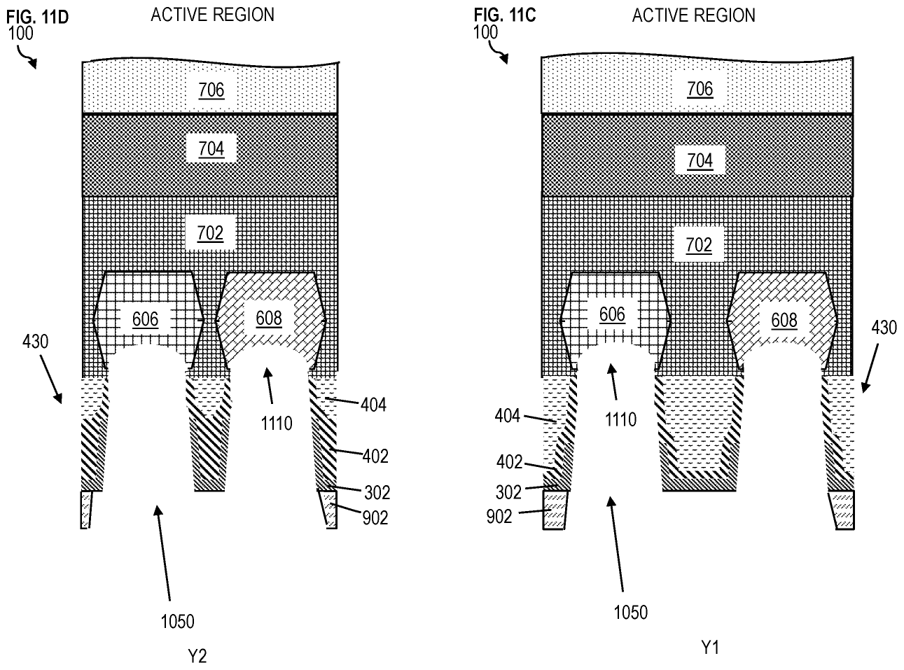

FIGS. 11A, 11B, 11C, and 11D depict the IC 100 after backside placeholder removal and optional gouging. Etching is performed to remove the first placeholder 602 in the trenches 1050 and the second placeholder 604 on top. Optionally, etching may continue to gouge into portions of the source/drain regions 606 and 608 forming cavities 1110. A reactive ion etch (RIE) may be utilized. The block mask layer 1002 can be removed, for example, by ashing the OPL.

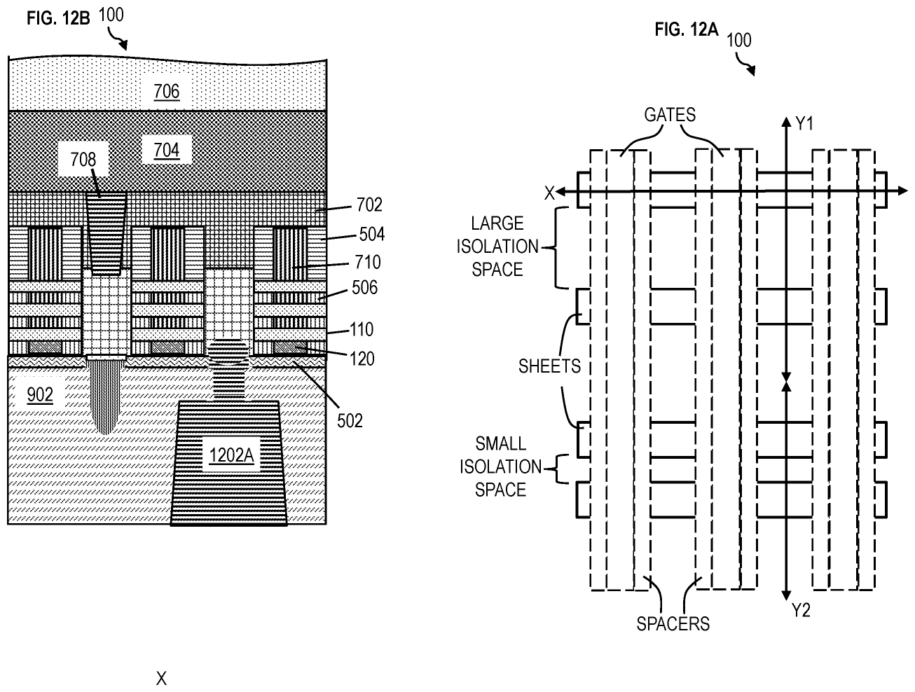

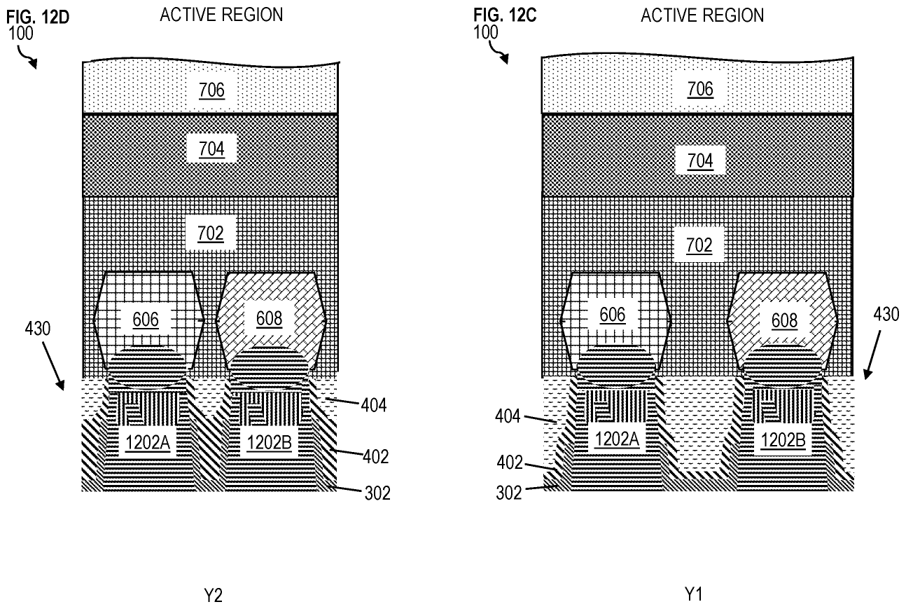

FIGS. 12A, 12B, 12C, and 12D depict the IC 100 after backside contact metallization and CMP stopping on the first STI liner. Conductive material is deposited to form metal contacts, such as backside S/D contacts 1202A and 1202B. A portion of the metal contacts may include silicide, resulting from the interface of the metal material and semiconductor material. CMP can be performed which stops on the first STI liner 302.

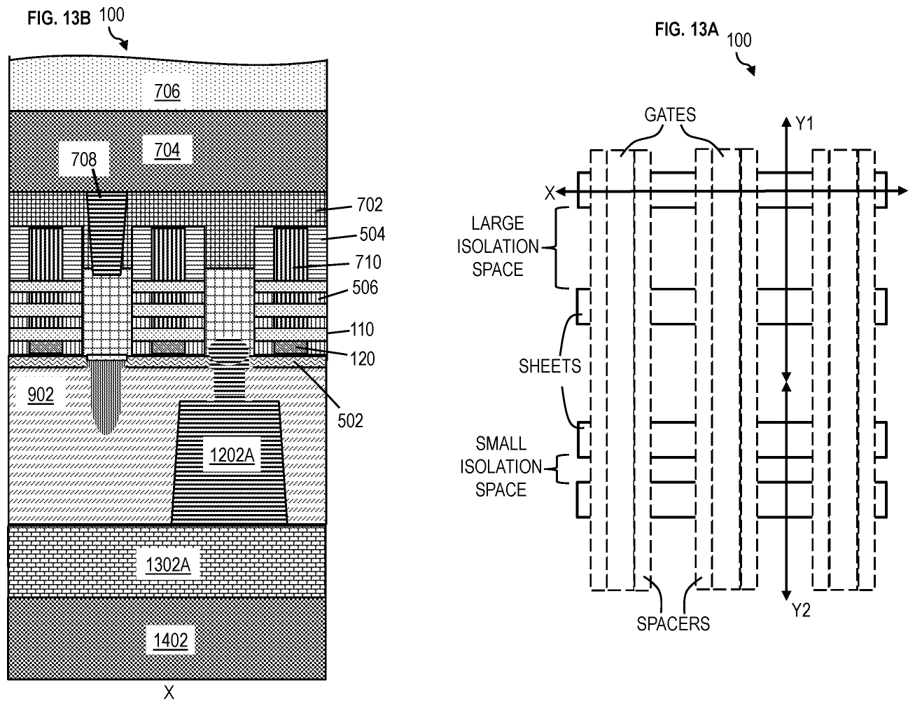

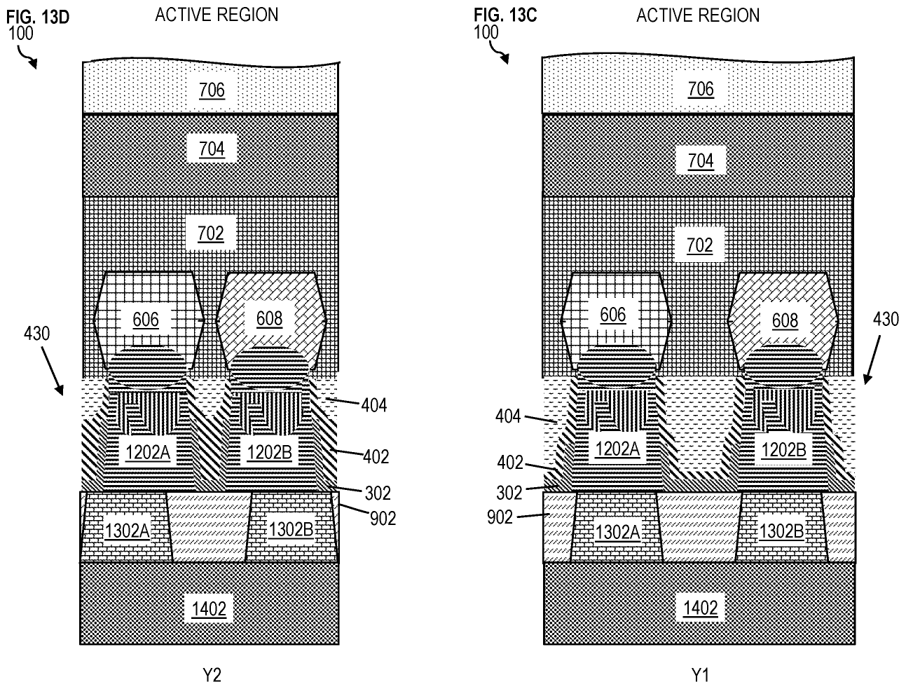

FIGS. 13A, 13B, 13C, and 13D depict the IC 100 after backside power rail and backside power delivery network formation. Further ILD fill material of the backside ILD material 902 is deposited and patterned to form cavities (not shown). Conductive material is deposited in the cavities to form backside power rails 1302A and 1302B, and then the backside power delivery network is formed.

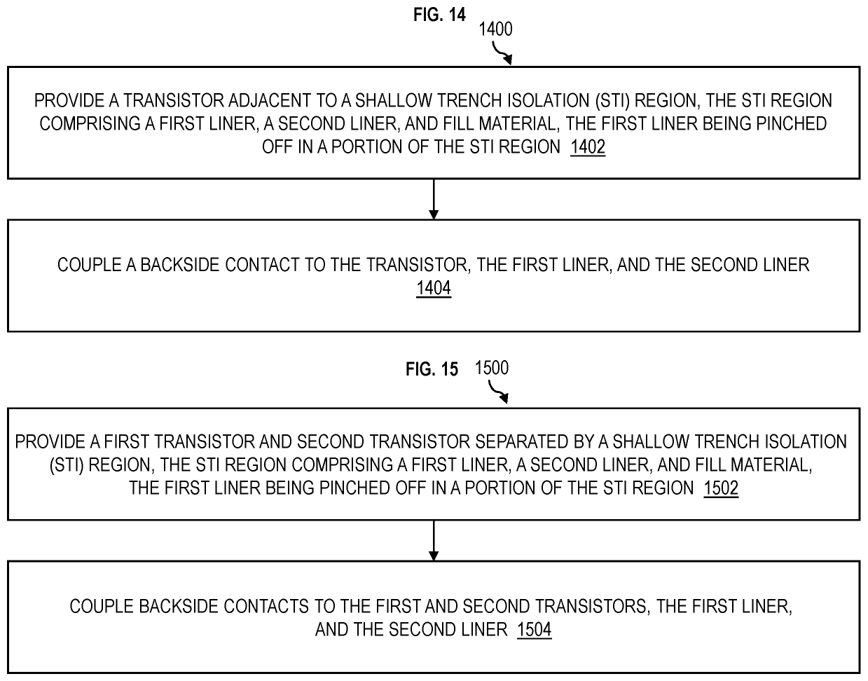

FIG. 14 depicts a flowchart of a method 1400 of forming a semiconductor structure (e.g., IC 100) according to one or more embodiments. Reference can be made to any of the figures discussed herein. At block 1402, the method 1400 includes providing a transistor (e.g., PFET or NFET) adjacent to a shallow trench isolation (STI) region, the STI region 430 includes a first liner (e.g., first STI liner 302), a second liner (e.g., second STI liner 402), and fill material (e.g., STI fill material 404), the second liner being pinched off in a portion of the STI region (e.g., the second STI liner 402 is pinched off in the STI regions 430 as depicted in the dashed circle 450). At block 1404, the method 1400 includes coupling a backside contact (e.g., backside S/D contacts 1202A and 1202B) to the transistor, the first liner, and the second liner.

Further, the backside contact (e.g., backside S/D contacts 1202A and 1202B) is connected to a side surface of the first liner (e.g., first STI liner 302). The backside contact (e.g., backside S/D contacts 1202A and 1202B) is connected to a side surface of the second liner (e.g., second STI liner 402). The transistor includes an epitaxial region (e.g., epitaxial source/drain regions 606 and 608), the backside contact being connected to the epitaxial region. The transistor includes an epitaxial region (e.g., epitaxial source/drain regions 606 and 608) having a cavity (e.g., cavities 1110), the backside contact being formed in the cavity of the epitaxial region. The first and second liners include different materials. The fill material is different from materials of the first and second liners.

FIG. 15 depicts a flowchart of a method 1500 of forming a semiconductor structure (e.g., IC 100) according to one or more embodiments. Reference can be made to any of the figures discussed herein. At block 1502, the method 1500 includes providing a first transistor (e.g., PFET) and second transistor (e.g., NFET) separated by a shallow trench isolation (STI) region, the STI region 430 including a first liner (e.g., first STI liner 302), a second liner (e.g., second STI liner 402), and fill material (e.g., STI fill material 404), the second liner being pinched off in a portion of the STI region (e.g., the second STI liner 402 is pinched off in the STI regions 430 as depicted in the dashed circle 450). At block 1504, the method 1500 includes coupling backside contacts (e.g., backside S/D contacts 1202A and 1202B) to the first and second transistors, the first liner, and the second liner.

In one or more embodiments, the ILD material can be SiO₂, SiN, a low-k dielectric material or an ultra-low-k dielectric material. Low-k dielectric materials may generally include dielectric materials having a k value of about 3.9 or less. The ultralow-k dielectric material generally includes dielectric materials having a k value less than 2.5. Unless otherwise noted, all k values mentioned in the present application are measured relative to a vacuum. Exemplary ultra-low-k dielectric materials generally include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultra-low-k dielectric material can be produced using a templated process or a sol-gel process as is generally known in the art. In the templated process, the precursor typically contains a composite of thermally labile and stable materials. After film deposition, the thermally labile materials can be removed by thermal heating, leaving pores in the dielectric film. In the sol gel process, the porous low-k dielectric films can be formed by hydrolysis and polycondensation of an alkoxide(s) such as tetraetehoxysilane (TEOS).

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20-C). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming the at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor structure comprising:
a transistor adjacent to a shallow trench isolation (STI) region, the STI region comprising a first liner, a second liner, and a fill material, the second liner being pinched off in a portion of the STI region; and
a backside contact coupled to the transistor, the first liner, and the second liner.

2. The semiconductor structure of claim 1, wherein the backside contact is connected to a side surface of the first liner.

3. The semiconductor structure of claim 1, wherein the backside contact is connected to a side surface of the second liner.

4. The semiconductor structure of claim 1, wherein the transistor comprises an epitaxial region, the backside contact being connected to the epitaxial region.

5. The semiconductor structure of claim 1, wherein the transistor comprises an epitaxial region having a cavity, the backside contact being formed in the cavity of the epitaxial region.

6. The semiconductor structure of claim 1, wherein the first and second liners comprise different materials.

7. The semiconductor structure of claim 1, wherein the fill material is different from materials of the first and second liners.

8. A method comprising:
providing a transistor adjacent to a shallow trench isolation (STI) region, the STI region comprising a first liner, a second liner, and a fill material, the second liner being pinched off in a portion of the STI region; and
coupling a backside contact to the transistor, the first liner, and the second liner.

9. The method of claim 8, wherein the backside contact is connected to a side surface of the first liner.

10. The method of claim 8, wherein the backside contact is connected to a side surface of the second liner.

11. The method of claim 8, wherein the transistor comprises an epitaxial region, the backside contact being connected to the epitaxial region.

12. The method of claim 8, wherein the transistor comprises an epitaxial region having a cavity, the backside contact being formed in the cavity of the epitaxial region.

13. The method of claim 8, wherein the first and second liners comprise different materials.

14. The method of claim 8, wherein the fill material is different from materials of the first and second liners.

15. A method comprising:
providing a first transistor and second transistor separated by a shallow trench isolation (STI) region, the STI region comprising a first liner, a second liner, and a fill material, the second liner being pinched off in a portion of the STI region; and
coupling backside contacts to the first and second transistors, the first liner, and the second liner.

16. The method of claim 15, wherein the backside contacts are connected to a side surface of the first liner.

17. The method of claim 15, wherein the backside contacts are connected to a side surface of the second liner.

18. The method of claim 15, wherein the first and second transistors comprise epitaxial regions, the backside contacts being connected to the epitaxial regions.

19. The method of claim 15, wherein the first and second transistors comprise epitaxial regions having cavities, the backside contacts being formed in the cavities of the epitaxial regions.

20. The method of claim 15, wherein the first and second liners comprise different materials.
